(19) United States
(12) Patent Application Publication
(10) Pub. No.: US 2025/0253614 A1
(43) Pub. Date: Aug. 7, 2025

(54) SEMICONDUCTOR OPTICAL DEVICE AND METHOD OF MANUFACTURING SEMICONDUCTOR OPTICAL DEVICE

(71) Applicant: Sumitomo Electric Industries, Ltd., Osaka-shi (JP)

(72) Inventor: Takuo HIRATANI, Osaka-shi (JP)

(73) Assignee: Sumitomo Electric Industries, Ltd., Osaka-shi (JP)

(21) Appl. No.: 19/022,668

(22) Filed: Jan. 15, 2025

(30) Foreign Application Priority Data
Feb. 6, 2024 (JP) 2024-016418

(51) Int. Cl. H01S 5/024; H01S 5/02; H01S 5/026

(52) U.S. Cl. CPC H01S 5/02461; H01S 5/021; H01S 5/0261

(57) ABSTRACT

A semiconductor optical device includes a substrate having a silicon layer, a semiconductor element includes a mesa, and the semiconductor element is formed of a III-V group compound semiconductor and has an optical gain. The silicon layer includes a waveguide, a recess, and a first slab portion. The recess is a recessed portion lower than a surface of the waveguide and a surface of the first slab portion, and the recess is provided on each of two sides of the waveguide. The first slab portion is connected to the waveguide. The semiconductor element is bonded to the first slab portion. The mesa is located on or above the first slab portion.

### CROSS REFERENCE TO RELATED APPLICATIONS

This application claims priority based on Japanese Patent Application No. 2024-016418, filed on Feb. 6, 2024, and the entire contents of the Japanese patent application are incorporated herein by reference.

### TECHNICAL FIELD

The present disclosure relates to a semiconductor optical device and a method of manufacturing of a semiconductor optical device.

### BACKGROUND

A semiconductor element formed of a compound semiconductor and having an optical gain is bonded to a substrate such as a silicon on insulator (SOI) substrate (silicon photonics) in which a waveguide is formed, whereby a hybrid semiconductor optical device can be formed (for example, Non-patent literature 1). After the bonding, etching or the like is performed on the semiconductor element. Light is transferred between the waveguide of silicon and the semiconductor element.

Non-patent literature 1: Alexander W. Fang, et al. “Electrically pumped hybrid AlGaInAs-silicon evanescent laser” OPTICS EXPRESS Vol. 14, No. 20, pp. 9203-9210 (2 Oct. 2006)

Non-Patent literature 2: Javad Rahimi, et al. “Demonstration of a High-Efficiency Short-Cavity III-V-on-Si C-Band DFB Laser Diode” IEEE JOURNAL OF SELECTED TOPICS IN QUANTUM ELECTRONICS, Vol. 28, No. 3, 820406 (May/June 2022)

### SUMMARY

A semiconductor optical device according to the present disclosure includes a substrate having a silicon layer, a semiconductor element includes a mesa, and the semiconductor element is formed of a III-V group compound semiconductor and has an optical gain. The silicon layer includes a waveguide, a recess, and a first slab portion. The recess is a recessed portion lower than a surface of the waveguide and a surface of the first slab portion, and the recess is provided on each of two sides of the waveguide. The first slab portion is connected to the waveguide. The semiconductor element is bonded to the first slab portion. The mesa is located on or above the first slab portion.

### BRIEF DESCRIPTION OF THE DRAWINGS

FIG. 1 is a plan view illustrating a semiconductor optical device according to a first embodiment.

FIG. 2A is a plan view enlarged around the transition structure.

FIG. 2B is a plan view illustrating a substrate.

FIG. 3A is a cross-sectional view illustrating a semiconductor optical device.

FIG. 3B is a cross-sectional view illustrating a semiconductor optical device.

FIG. 4A is a cross-sectional view illustrating a semiconductor optical device.

FIG. 4B is a cross-sectional view illustrating a semiconductor optical device.

FIG. 5 is a cross-sectional view illustrating a semiconductor optical device.

FIG. 6 is a diagram illustrating optical output.

FIG. 7 is a cross-sectional view illustrating a method of manufacturing of a semiconductor optical device.

FIG. 8 is a cross-sectional view illustrating a method of manufacturing of a semiconductor optical device.

FIG. 9 is a cross-sectional view illustrating a method of manufacturing of a semiconductor optical device.

FIG. 10 is a cross-sectional view illustrating a semiconductor optical device according to a second embodiment.

### DETAILED DESCRIPTION

The semiconductor element bonded to the substrate is an active element and generates heat when driven. A groove (trench) is provided on each of two sides of the waveguide in the substrate. The inside of the groove is filled with air or a dielectric material. The heat dissipation of the groove is lower than that of the portion of the substrate other than the groove. The characteristics may be deteriorated due to the increase in temperature. Thus, an object is to provide a semiconductor optical device capable of enhancing heat dissipation and a method of manufacturing of the semiconductor optical device.

### Description of Embodiments of Present Disclosure

First, the contents of embodiments of the present disclosure will be listed and explained.

(1) A semiconductor optical device according to one aspect of the present disclosure includes a substrate having a silicon layer, a semiconductor element includes a mesa, and the semiconductor element is formed of a III-V group compound semiconductor and has an optical gain. The silicon layer includes a waveguide, a recess, and a first slab portion. The recess is a recessed portion lower than a surface of the waveguide and a surface of the first slab portion, and the recess is provided on each of two sides of the waveguide. The first slab portion is connected to the waveguide. The semiconductor element is bonded to the first slab portion. The mesa is located on or above the first slab portion. Since the semiconductor element is bonded to the first slab portion, heat dissipation is increased. Heat generated in the semiconductor element is released through the first slab portion. By suppressing temperature rise, deterioration of the characteristics of the semiconductor optical device is suppressed. The mode shape of light is controlled by the mesa of the semiconductor element. It is possible to reduce the loss of light.

(2) In the above (1), the first slab portion may extend directly under the mesa and in a range extending from an end of the mesa by 3 μm or more. Heat is generated in the mesa. Since the first slab portion is located directly under the mesa and in a range of 3 μm or more from the end of the mesa, heat dissipation is increased. The mode shape of the light propagating in the first slab portion is maintained. It is possible to reduce the loss of light.

(3) In the above (1) or (2), the semiconductor element may include a second slab portion. The second slab portion may be bonded to the first slab portion. The mesa may be located on or above the second slab portion. Since the first slab portion and the second slab portion are bonded each other, the contact area increases. Heat dissipation and bonding strength are increased.

(4) In the above (3), the semiconductor element may have a first semiconductor layer, an active layer, and a second semiconductor layer. The first semiconductor layer, the active layer, and the second semiconductor layer may be stacked so as to be located closer to the substrate in this order. The first semiconductor layer may have a first conductivity type. The second semiconductor layer may have a second conductivity type. The mesa may include the second semiconductor layer. The second slab portion may include the first semiconductor layer and the active layer. A current flows through the mesa, carriers are injected into the active layer, and light is generated. Heat is generated by the current flowing through the mesa. Since the first slab portion is located under the mesa, heat dissipation is high and temperature rise can be suppressed.

(5) In the above (4), the semiconductor optical device may include a first electrode separated from the mesa and electrically connected to the first semiconductor layer, and a second electrode provided on or above the mesa and electrically connected to the second semiconductor layer. The first slab portion may extend from under the mesa to under the second electrode. A current flows between the first electrode and the second electrode. The first slab portion is located under the current path. Heat dissipation is increased, and heat can be effectively released.

(6) In any one of the above (3) to (5), the semiconductor element may include a projecting portion. The projecting portion may project from the second slab portion to be located on or above the waveguide. It is possible to reduce the loss of light by enhancing the coupling efficiency between the semiconductor element and the substrate.

(7) In any one of the above (1) to (6), the semiconductor element may include two dummy mesas. The two dummy mesas may be located one each on two sides of the mesa. The stress concentration on the mesa can be suppressed.

(8) In any one of the above (1) to (7), the semiconductor element may be in contact with the silicon layer. Heat dissipation can be enhanced.

(9) A method of manufacturing a semiconductor optical device includes: bonding a semiconductor element to a silicon layer of a substrate, the semiconductor element being formed of a III-V group compound semiconductor and having an optical gain; and forming a mesa at the semiconductor element that has been bonded. The silicon layer includes a waveguide, a recess, and a slab portion. The recess is a recessed portion lower than a surface of the waveguide and a surface of the slab portion, and the recess is provided on each of two sides of the waveguide. The slab portion is connected to the waveguide. In the bonding, the semiconductor element is bonded to the slab portion. The mesa is located on or above the slab portion. Since the semiconductor element is bonded to the slab portion, heat dissipation is increased. Heat generated in the semiconductor element is released through the slab portion. By suppressing temperature rise, deterioration of the characteristics of the semiconductor optical device is suppressed. The mode shape of light is controlled by the mesa of the semiconductor element. It is possible to reduce the loss of light.

### Details of Embodiments of Present Disclosure

Specific examples of a semiconductor optical device and a method of manufacturing of a semiconductor optical device according to embodiments of the present disclosure will be described below with reference to the drawings. It is noted that, the present disclosure is not limited to these examples, but is defined by the scope of the claims, and is intended to include all modifications within the meaning and scope equivalent to the scope of the claims.

### First Embodiment

### (Semiconductor Optical Device)

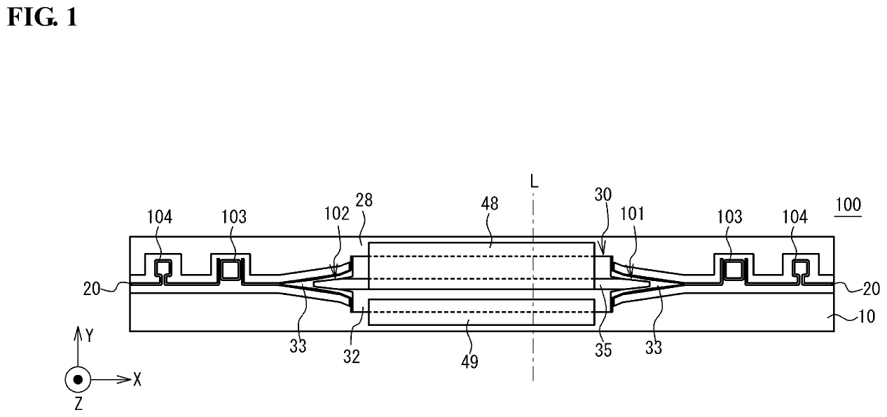

FIG. 1 is a plan view illustrating a semiconductor optical device 100 according to a first embodiment. Semiconductor optical device 100 is a hybrid type wavelength tunable laser diode, and includes a substrate 10, a semiconductor element 30, an electrode 48 (second electrode), and an electrode 49 (first electrode). Semiconductor element 30 has an optical gain and is bonded to one surface of substrate 10. The Z-axis direction is a normal direction of a top surface of substrate 10. The X-axis direction is a direction parallel to a waveguide. The Y-axis direction is orthogonal to the X-axis direction and the Z-axis direction.

Semiconductor optical device 100 includes a transition structure 101, a transition structure 102, two ring resonators 103, and two loop mirrors 104. In the X-axis direction, loop mirror 104, ring resonator 103, transition structure 102, semiconductor element 30, transition structure 101, ring resonator 103, and loop mirror 104 are arranged in this order. A laser resonator is formed by these components.

Ring resonator 103 and loop mirror 104 are provided on substrate 10. Transition structure 101 and transition structure 102 are portions that cause light to transfer between substrate 10 and semiconductor element 30, and are formed of substrate 10 and semiconductor element 30.

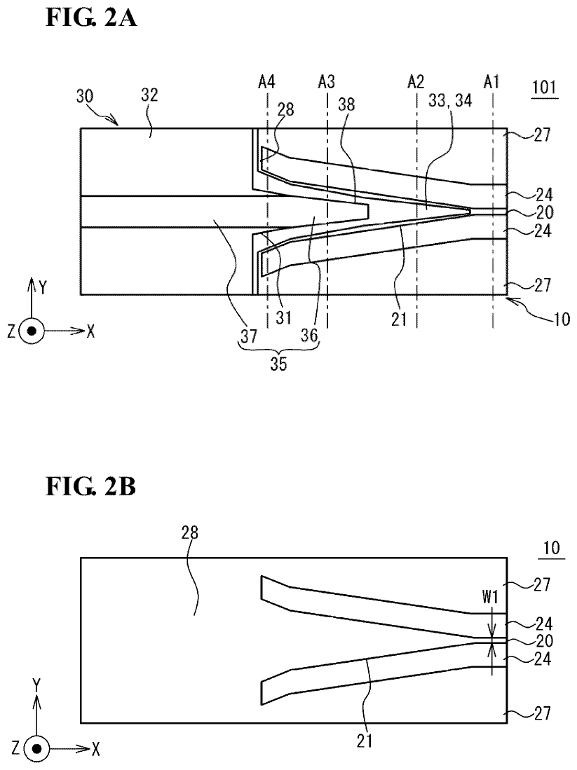

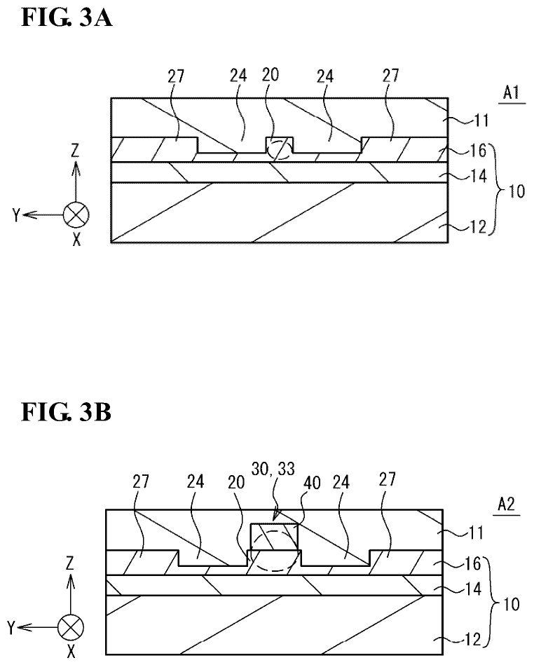

FIG. 2A is a plan view enlarged around transition structure 101. FIG. 2B is a plan view illustrating substrate 10, in which semiconductor element 30 is removed from FIG. 2A. FIG. 3A to FIG. 5 are cross-sectional views illustrating semiconductor optical device 100, in which cross-sections taken along a line A1, a line A2, a line A3, a line A4 of FIG. 2A, and line L of FIG. 1 are illustrated, respectively. The light distribution is illustrated by dashed lines in FIG. 3A to FIG. 5.

As illustrated in FIG. 3A to FIG. 5, substrate 10 is a silicon on insulator (SOI) substrate, and includes a substrate 12, a BOX layer 14, and a silicon (Si) layer 16, which are stacked in order in the Z-axis direction. Substrate 12 is formed of, for example, Si. BOX layer 14 is formed of, for example, silicon oxide (SiO₂). The thickness of BOX layer 14 is, for example, 3 μm. The thickness of silicon layer 16 is, for example, 220 nm. The top surface of substrate 10 and a surface of semiconductor element 30 are covered with an insulating film 11. Insulating film 11 is formed of, for example, SiO₂ having a thickness of 1 μm. The refractive index of silicon layer 16 is 3.45. The refractive index of each of BOX layer 14 and insulating film 11 is 1.45, which is lower than that of silicon layer 16. A functional portion such as a waveguide is provided in silicon layer 16 of substrate 10.

As illustrated in FIG. 1, FIG. 2A and FIG. 2B, substrate 10 has a waveguide 20, a recess 24, a terrace 27 and a slab portion 28 (first slab portion). As illustrated in FIG. 1, waveguides 20 are connected to both ends of slab portion 28 in the X-axis direction. Slab portion 28 extends from transition structure 101 to transition structure 102.

As illustrated in FIG. 2B, waveguide 20 is parallel to the X-axis direction. Waveguide 20 has a tapered portion 21. A width of tapered portion 21 increases as a distance from slab portion 28 decreases and decreases as the distance from slab portion 28 increases. A width W1 at a tip of waveguide 20 illustrated in FIG. 2B is, for example, 420 nm.

In the Y-axis direction, recess 24 and terrace 27 are provided in this order on each of two sides of waveguide 20. That is, recess 24 is disposed adjacent to waveguide 20. Terrace 27 is placed on the opposite side of recess 24 from waveguide 20. Recess 24 extends along waveguide 20 and has a taper shape corresponding to tapered portion 21 of waveguide 20.

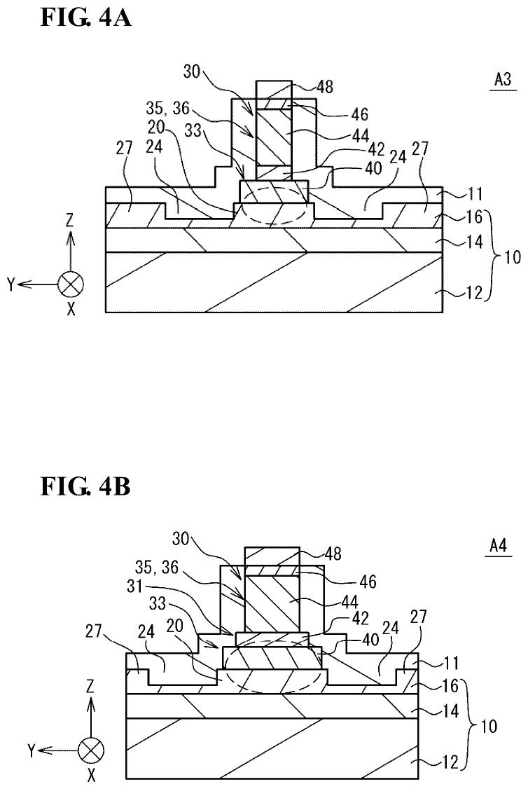

As illustrated in FIG. 3A to FIG. 4B, waveguide 20 and terrace 27 are portions of silicon layer 16 which project from recess 24 in the Z-axis direction (upward). A surface of waveguide 20 is located at the same height as a surface of terrace 27. Recess 24 is a recessed portion lower than the surfaces of waveguide 20 and terrace 27. Silicon layer 16 forms a bottom surface of recess 24. The thickness of silicon layer 16 in the recess is, for example, 30 nm. Recess 24 may extend to the middle of silicon layer 16 in the Z-axis direction, or may extend to BOX layer 14 through silicon layer 16. Insulating film 11 is embedded in recess 24.

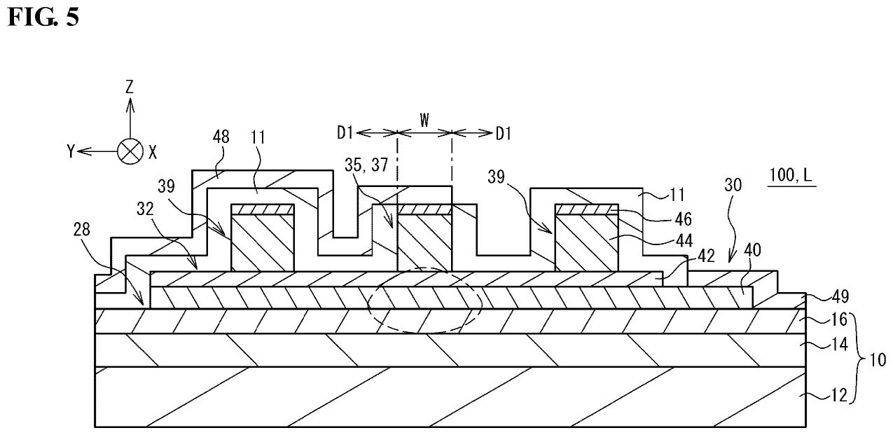

As illustrated in FIG. 2B, in the Y-axis direction, slab portion 28 has a width lager than that of waveguide 20 and is connected to terrace 27 on each of two sides of waveguide 20. That is, no recess is provided between slab portion 28 and terrace 27. As illustrated in FIG. 5, slab portion 28 is a plate-like portion. A surface of slab portion 28 is located at the same height as the surface of terrace 27. Slab portion 28 is integral with terrace 27 and extends parallel to the XY plane, and forms a surface of silicon layer 16.

As illustrated in FIG. 1, semiconductor element 30 includes a slab portion 32 (second slab portion), two projecting portions 33, and a mesa 35. In the X-axis direction, projecting portion 33, slab portion 32, and projecting portion 33 are arranged in order. Slab portion 32 and mesa 35 extend from one transition structure 101 to the other transition structure 102.

As illustrated in FIG. 2A, slab portion 32 is bonded to slab portion 28 of substrate 10. A lower surface of slab portion 32 is in contact with a top surface of slab portion 28. Slab portion 32 is plate-shaped and has a width larger than projecting portion 33 and mesa 35. The planar shape of slab portion 32 is rectangular. In a plan view, slab portion 32 does not protrude outward from slab portion 28. Slab portion 28 extends from a position at which slab portion 28 overlaps slab portion 32 to the outside of slab portion 32.

Projecting portion 33 extends parallel to the X-axis, projects from slab portion 32 to be located on waveguide 20, and is located on tapered portion 21 of waveguide 20. Projecting portion 33 has a tapered portion 34. In the example of FIG. 2A, entire projecting portion 33 is tapered portion 34. A width of tapered portion 34 increases as a distance from slab portion 32 decreases and decreases as the distance from slab portion 32 increases. Projecting portion 33 has a width larger than mesa 35. A width of projecting portion 33 at the portion where projecting portion 33 is connected to slab portion 32 is, for example, 5.7 μm.

As illustrated in FIG. 2A, mesa 35 extends parallel to the X-axis from a position at which mesa 35 overlaps waveguide 20 to a position at which mesa 35 overlaps slab portion 28. Mesa 35 is located on or above slab portion 28, slab portion 32, and projecting portion 33. Mesa 35 has a portion 36 and a portion 37. Portion 36 projects out of slab portion 32 in the X-axis direction and is located on or above projecting portion 33 and waveguide 20. Portion 37 is located on slab portion 32.

Portion 36 of mesa 35 has a tapered portion 38 (third tapered portion). Tapered portion 38 is located on or above projecting portion 33. A width of tapered portion 38 increases as a distance from slab portion 32 decreases and decreases as the distance from slab portion 32 increases. A width at a tip of mesa 35 is, for example, 400 nm.

Projecting portion 33 and mesa 35 do not protrude outward from waveguide 20 in a plan view, and are located on an inner side of waveguide 20. Waveguide 20 protrudes from under projecting portion 33 and mesa 35 to the outside of projecting portion 33.

A tapered portion 31 of semiconductor element 30 projects from slab portion 32 in the X-axis direction, is located on two sides of mesa 35 in the Y-axis direction, and is located between slab portion 32 and tapered portion 38 of mesa 35 in the X-axis direction. A width of a portion of tapered portion 31 connected to slab portion 32 is, for example, 3 μm.

As illustrated in FIG. 3B to FIG. 5, semiconductor element 30 has a cladding layer 40 (first semiconductor layer), an active layer 42, a cladding layer 44, and a contact layer 46 (the last two layers constitute a second semiconductor layer). As illustrated in FIG. 3B to FIG. 4A, projecting portion 33 of semiconductor element 30 is formed of cladding layer 40. As illustrated in FIG. 4A, tapered portion 31 is formed of active layer 42.

Mesa 35 includes active layer 42, cladding layer 44, and contact layer 46. As illustrated in FIG. 4A and FIG. 4B, portion 36 of mesa 35 includes active layer 42, cladding layer 44, and contact layer 46, and has a deep ridge structure. As illustrated in FIG. 5, portion 37 of mesa 35 does not include active layer 42, but has cladding layer 44 and contact layer 46, and has a shallow ridge structure. A width W of portion 37 of mesa 35 is, for example, 1 μm to 3 μm.

As illustrated in FIG. 5, semiconductor element 30 includes two dummy mesas 39. Two dummy mesas 39 are located one each on two sides of mesa 35 in the Y-axis direction and are separated from mesa 35. Dummy mesa 39 includes cladding layer 44 and contact layer 46. The height of dummy mesa 39 is equal to the height of mesa 35. The length of dummy mesa 39 in the X-axis direction is equal to the length of portion 37 of mesa 35, for example.

As illustrated in FIG. 5, slab portion 32 includes cladding layer 40 and active layer 42. Slab portion 28 of silicon layer 16 is provided under slab portion 32. Slab portion 28 is provided at least directly below mesa 35. The slab portion 28 is provided at least in a range of distances D1 or more from both ends of mesa 35 in the Y-axis direction. The distance D1 may be, for example, 3 μm or 5 μm. In the example of FIG. 5, slab portion 32 is provided directly under portion 37 of mesa 35 between mesa 35 and two dummy mesas 39, under dummy mesas 39, and outside of dummy mesas 39 in the Z-axis direction. That is, slab portion 32 extends from under portion 37 of mesa 35 to the outside of two dummy mesas 39. Slab portion 28 may extend to the end of semiconductor optical device 100 in the Y-axis direction.

Cladding layer 40 is located between active layer 42 and silicon layer 16 of substrate 10, and extends outward in the Y-axis direction from active layer 42. Cladding layer 40 is in contact with silicon layer 16. Slab portion 28 may extend from directly under mesa 35 to outside of dummy mesa 39.

Insulating film 11 covers substrate 10, slab portion 32, projecting portion 33, mesa 35, and dummy mesa 39. As illustrated in FIG. 5, insulating film 11 has an opening portion on mesa 35. Electrode 48 is a p-type electrode, is provided on a surface of insulating film 11 and a top surface of mesa 35, and is in contact with a surface of contact layer 46 in the opening portion of insulating film 11, and is electrically connected to contact layer 46.

Electrode 48 extends from the top surface of mesa 35 to one dummy mesa 39, covers a top surface and side surfaces of dummy mesa 39, and extends to the outside of slab portion 32. Insulating film 11 is provided between electrode 48 and dummy mesa 39 and slab portion 32. Electrode 48 is electrically connected to contact layer 46 of mesa 35, but is not connected to contact layer 46 of dummy mesa 39 and cladding layer 40.

Insulating film 11 also has an opening portion at a position separated from mesa 35 and dummy mesa 39. Electrode 49 is an n-type electrode and is electrically connected to cladding layer 40 through the opening portion. Electrode 49 is located on slab portion 32 and slab portion 28.

Cladding layer 40 is formed of, for example, n-type (first conductivity type) indium phosphide (n-InP). The thickness of cladding layer 40 is, for example, 400 nm. Active layer 42 has a multiple quantum well (MQW) and includes a barrier layer and a well layer. The plurality of barrier layers and the plurality of well layers are alternately stacked. The barrier layer and the well layer are formed of, for example, i-type gallium indium arsenide phosphide (GaInAsP). The thickness of active layer 42 is, for example, 200 nm. A guide layer may be provided between active layer 42 and cladding layer 40, and between active layer 42 and cladding layer 44. Cladding layer 44 is formed of, for example, p-type (second conductivity type) indium phosphide (p-InP). The thickness of cladding layer 44 is, for example, 2 μm. Contact layer 46 is formed of, for example, p-type gallium indium arsenide (p-GalInAs). The semiconductor layer of semiconductor element 30 may be formed of a III-V group compound semiconductor other than the above.

Electrode 48 and electrode 49 are formed of a metal. Electrode 48 is formed of a stacked body in which titanium (Ti), platinum (Pt), and gold (Au) are stacked so as to be located closer to mesa 35, for example. Electrode 49 is formed of, for example, an alloy of gold, germanium, and nickel (AuGeNi).

Transition structure 102 has the same structure as transition structure 101. Slab portion 28 of silicon layer 16 and slab portion 32 of semiconductor element 30 extend from transition structure 101 to transition structure 102.

A voltage is applied to semiconductor element 30 by using electrode 48 and electrode 49, and carriers are injected into active layer 42. Active layer 42 has an optical gain and generates light by carrier injection. The wavelength of the light is, for example, 1.55 μm. Semiconductor element 30 and substrate 10 are optically coupled by evanescent optical coupling. The light generated in semiconductor element 30 is transferred to waveguides 20 in transition structure 101 and transition structure 102. The light resonates in ring resonator 103 and is reflected by loop mirror 104. The reflected light propagates toward semiconductor element 30, and is transferred from waveguide 20 to semiconductor element 30 in transition structure 101 and transition structure 102. The light is repeatedly reflected, and thus laser oscillation occurs.

The diameter of one of two ring resonators 103 is different from the diameter of the other. The oscillation wavelength is determined by the vernier effect of two ring resonators 103. The transmittance of one of two loop mirrors 104 is higher than the transmittance of the other. A part of the laser light is transmitted through loop mirror 104 and emitted to the outside of semiconductor optical device 100.

In FIG. 3A to FIG. 5, the shape of the light is schematically illustrated by a closed curve with a dashed line. The mode of the light is defined by waveguide 20 and mesa 35. As illustrated in FIG. 3A, light is intensively distributed in waveguide 20 before tapered portion 21. In transition structure 101, light is transferred from waveguide 20 to semiconductor element 30. Since each of projecting portion 33 and mesa 35 of semiconductor element 30 has a taper shape, the light gradually transfers, and the mode of the light is slowly converted. As illustrated in FIG. 5, silicon layer 16 has slab portion 28. Mesa 35 is located above slab portion 28. Light is confined around mesa 35 of semiconductor element 30 and is less likely to spread. While the light propagates through semiconductor element 30, the mode of the light after conversion is maintained. It is possible to reduce the loss of light.

When a voltage is applied to semiconductor element 30, a current flows between electrode 48 and electrode 49. The current flows through contact layer 46, cladding layer 44, active layer 42, and cladding layer 40 of semiconductor element 30. The flow of current generates heat. As illustrated in FIG. 5, slab portion 28 of silicon layer 16 extends under electrodes 48 and 49, from a portion under electrode 48 to a portion under electrode 49. In other words, in a portion located below the current path, silicon layer 16 is not provided with an air hole such as a groove, but is provided with slab portion 28. The thermal resistance of silicon is lower than that of air. Since slab portion 28 is located, heat dissipation increases. Silicon layer 16 functions as a heat dissipation path. Heat generated when semiconductor optical device 100 is driven is released from silicon layer 16. Deterioration of characteristics due to temperature rise is suppressed.

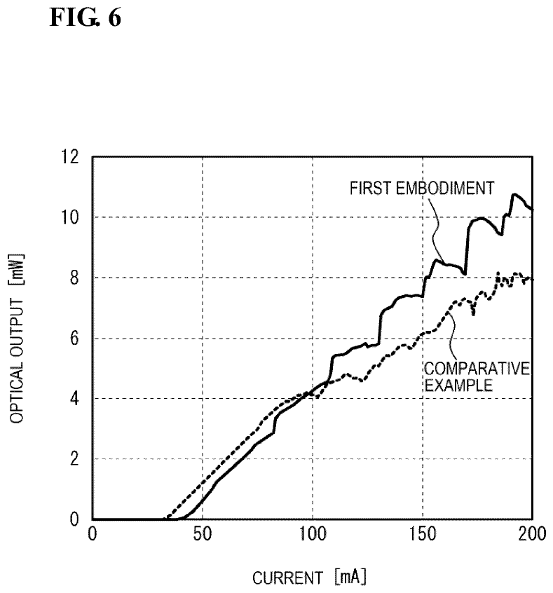

FIG. 6 is a diagram illustrating optical output. The horizontal axis represents the current flowing through semiconductor element 30. The vertical axis represents the output of light emitted from the semiconductor optical device. The solid line represents the measurement result of the optical output in the first embodiment. The dotted line represents the measurement result in the comparative example. In the comparative example, the waveguide and the recess of silicon layer 16 extend from the outside of semiconductor element 30 to under semiconductor element 30. A width of the waveguide is 1 μm. The wavelength of the light is 1.55 μm.

As illustrated in FIG. 6, the optical output increases as the current increases. Under the condition that the current is 100 mA or more, the optical output of the first embodiment is higher than the optical output of the comparative example when compared with the same current.

In the comparative example, a recess of silicon layer 16 is also provided under semiconductor element 30. The recess is filled with air. The recess has low heat dissipation, and thus heat generated from semiconductor element 30 is less likely to release. Since the temperature is easily increased, the characteristics are deteriorated. As illustrated in FIG. 5, the optical output is less likely to increase.

In the first embodiment, the recess is not provided under semiconductor element 30, and slab portion 28 is provided. Since the heat dissipation is high, heat is easily released and the temperature is less likely to rise. The deterioration of the characteristics caused by the temperature rise is suppressed. As the current increases, the amount of heat generated increases, and thus high heat dissipation is required. As illustrated in FIG. 5, the higher the current, the larger the difference in optical output between the first embodiment and the comparative example. The optical output of the first embodiment is about 1.3 times the optical output of the comparative example.

### (Manufacturing Method)

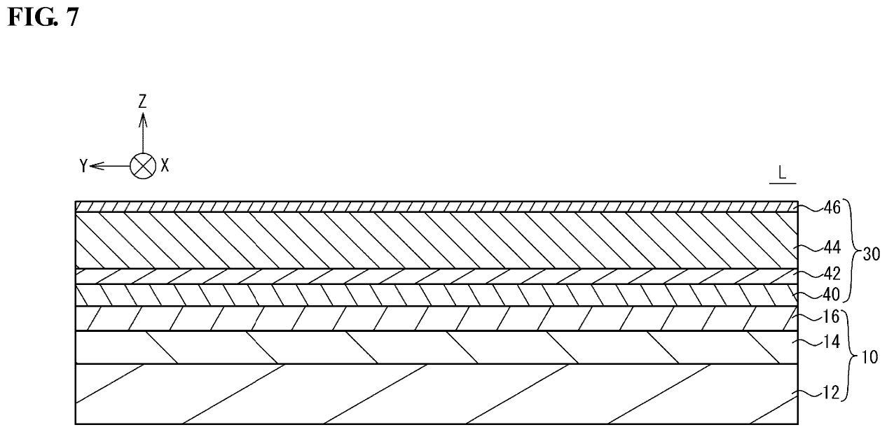

FIG. 7 to FIG. 9 are cross-sectional views illustrating a method of manufacturing of semiconductor optical device 100, in which a cross-section at a position corresponding to FIG. 5 is illustrated.

In a step prior to FIG. 7, for example, dry-etching is performed on silicon layer 16 of substrate 10. A portion exposed from a mask (not illustrated) is etched to form recess 24. A portion covered with the mask (not illustrated) is not etched. Waveguide 20, terrace 27 and slab portion 28 are formed.

On an InP substrate different from the SOI substrate (substrate 10), contact layer 46, cladding layer 44, active layer 42, and cladding layer 40 are epitaxially grown in order by metal organic chemical vapor deposition (MOCVD) or the like. The InP substrate is diced to form semiconductor element 30. Semiconductor element 30 immediately after dicing is a rectangular parallelepiped, and does not have slab portion 32, projecting portion 33, and mesa 35.

As illustrated in FIG. 7, semiconductor element 30 is bonded to the top surface of substrate 10. One surface of silicon layer 16 and a surface of cladding layer 40 of semiconductor element 30 are irradiated with plasma to activate these surfaces. The surface of cladding layer 40 is brought into contact with the surface of silicon layer 16, and semiconductor element 30 is bonded to silicon layer 16. Semiconductor element 30 covers, for example, a top surface of silicon layer 16 and is located on or above waveguide 20, recess 24, terrace 27, and slab portion 28. After the bonding, the InP substrate is removed by wet-etching. The semiconductor layers from contact layer 46 to cladding layer 40 remain.

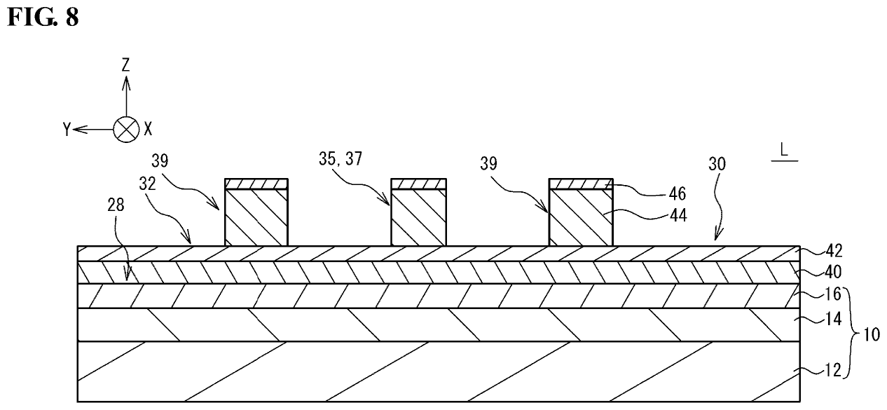

As illustrated in FIG. 8, mesa 35 and dummy mesas 39 are formed in semiconductor element 30. Mesa 35 and dummy mesas 39 are located above slab portion 28. Specifically, a mask (not illustrated) is provided on the top surface of contact layer 46. Contact layer 46 and cladding layer 44 are etched at portions not covered with the mask. Mesa 35 and dummy mesas 39 are formed in the portion covered with the mask. For example, contact layer 46 and cladding layer 44 may be removed by wet-etching using a hydrochloric acid-based etchant. Contact layer 46 and cladding layer 44 may be dry-etched to the middle, and the remaining portion may be wet-etched. Active layer 42 and cladding layer 40 remain in the etched portion and are located under mesa 35 and dummy mesas 39 to form slab portion 32.

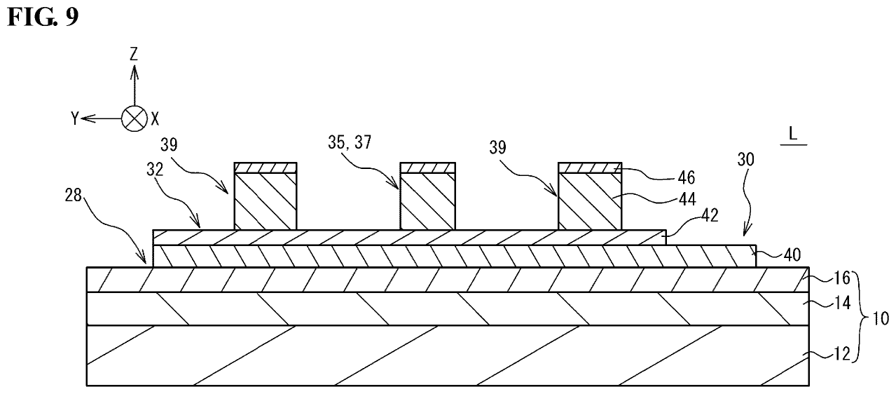

As illustrated in FIG. 9, active layer 42 and cladding layer 40 are etched. A portion of cladding layer 40 is exposed from active layer 42. Projecting portion 33 illustrated in FIG. 2B is also formed.

Insulating film 11 is formed by a plasma enhanced chemical vapor deposition method (PECVD) or the like as illustrated in FIG. 3A to FIG. 5. An opening portion of insulating film 11 is formed on mesa 35, and an opening portion is also formed on cladding layer 40. Electrode 48 and electrode 49 are formed in the opening portions by vacuum deposition or the like. Semiconductor optical device 100 is formed by the above steps.

According to the first embodiment, silicon layer 16 of substrate 10 has waveguide 20, recess 24, and slab portion 28. Since semiconductor element 30 is bonded to slab portion 28, heat dissipation is high. Heat generated in semiconductor element 30 is released through slab portion 28. By suppressing temperature rise, deterioration of the characteristics of semiconductor optical device 100 is suppressed. For example, as illustrated in FIG. 6, a high optical output can be obtained.

Mesa 35 of semiconductor element 30 is located above slab portion 28. Light is distributed in the vicinity of mesa 35, and the mode shape is controlled by mesa 35. The mode of light is distributed over the lower portion of mesa 35, slab portion 32, and slab portion 28. Slab portion 28 is provided directly under mesa 35 and in a range of the distance D1 or more from the end of mesa 35. The distance D1 is 3 μm or more. When the distance D1 is 3 μm or more, the mode of light entering from waveguide 20 is stably maintained in the vicinity of mesa 35. For example, single-mode light can be propagated by mesa 35, slab portion 32, and slab portion 28. It is possible to reduce the loss of light.

Semiconductor element 30 is bonded to slab portion 28. The contact area between semiconductor element 30 and silicon layer 16 is increased and the bonding strength is increased as compared with the case where semiconductor element 30 is bonded onto recess 24. The mechanical strength of semiconductor optical device 100 is improved. The etchant used in the wet-etching is blocked by slab portion 28. Etching of semiconductor element 30 from the bonding interface is reduced. Damage to semiconductor element 30 can be suppressed.

When a voltage is applied, a current flows through mesa 35, and heat is generated. Slab portion 28 of silicon layer 16 is provided at least directly under mesa 35 and over a range of the distance D1 or more from the end of mesa 35. The distance D1 is, for example, 1 μm or more, 3 μm or more, or 5 μm or more. Slab portion 28 may be provided in a range wider than a width of slab portion 32 in the Y-axis direction. Slab portion 28 functions as a heat dissipation path, and heat generated in mesa 35 is released. Heat dissipation is increased. Heat spreads in the XY direction in slab portion 28 and slab portion 32. In a plan view, a recess having a small range that does not divide the heat dissipation path may be provided in a portion of slab portion 28 under slab portion 32. “The division of the heat dissipation path” means that the recess penetrates slab portion 28 located below slab portion 32 in a plan view. Even when a small recess that does not divide the heat dissipation path is provided, it is preferable that the small recess is not provided directly under mesa 35 or in a range of the distance D1 (for example, the D1 is 3 μm) from the end of mesa 35. It is possible to reduce the loss of light.

As illustrated in FIG. 5, slab portion 28 may extend from under mesa 35 to outside of electrode 49. The current flows between electrode 48 provided in mesa 35 and electrode 49. Heat is generated in the current path. Slab portion 28 is provided at a position at which slab portion 28 overlaps the current path in plan view. Heat dissipation is increased, and heat can be effectively released.

No resin or the like is provided between semiconductor element 30 and silicon layer 16, and semiconductor element 30 is directly in contact with silicon layer 16. Heat is easily conducted from semiconductor element 30 to silicon layer 16, and heat dissipation is increased.

In the example illustrated in FIG. 1 and FIG. 5, recess 24 is not provided at a position at which recess 24 overlaps semiconductor element 30, and slab portion 28 is located. The heat dissipation is increased. Slab portion 28 is in contact with the entire lower surface of semiconductor element 30. The contact area between semiconductor element 30 and silicon layer 16 increases, and the bonding strength increases.

Semiconductor element 30 has slab portion 32. Slab portion 32 of semiconductor element 30 is bonded to slab portion 28 of silicon layer 16. The slab portions are bonded to each other, and thus the contact area increases. Heat dissipation and bonding strength are increased. Mesa 35 is located on slab portion 32. The mode of light can be controlled by mesa 35. It is possible to reduce the loss of light.

Semiconductor element 30 has cladding layer 40, active layer 42, cladding layer 44, and contact layer 46. Slab portion 32 includes cladding layer 40 and active layer 42. Portion 37 of mesa 35 includes cladding layer 44 and contact layer 46. Cladding layer 40 which is n-type, active layer 42 which is i-type, cladding layer 44 which is p-type, and contact layer 46 which is p-type are stacked, and a p-i-n (positive-intrinsic-negative) bond is formed in mesa 35. Carriers are injected into active layer 42, and light can be generated. Heat is generated by the current flowing through mesa 35. Since slab portion 28 is located under mesa 35, heat dissipation is high, and temperature rise can be suppressed.

Semiconductor element 30 has projecting portion 33. Projecting portion 33 is located on waveguide 20. The coupling efficiency between semiconductor element 30 and substrate 10 can be increased, and the light can be slowly transferred. Portion 37 of mesa 35 is located on slab portion 32 and includes cladding layer 44 and contact layer 46. The light is confined around mesa 35. It is possible to reduce the loss of light.

As illustrated in FIG. 2A, waveguide 20 protrudes outward of projecting portion 33 and mesa 35. Projecting portion 33 and mesa 35 do not protrude, and are located on the inner side of waveguide 20. Etching of semiconductor element 30 from the bonding interface can be reduced. Mesa 35 is located on the inner side of projecting portion 33. Projecting portion 33 and mesa 35 are easy to manufacture by etching. After mesa 35 is formed, it is only necessary that projecting portion 33 is formed under mesa 35.

Waveguide 20 has tapered portion 21. Projecting portion 33 has tapered portion 34. Mesa 35 has tapered portion 38. Tapered portion 34 of projecting portion 33 is bonded to tapered portion 21 of waveguide 20. Tapered portion 38 of mesa 35 is located on or above tapered portion 34 of projecting portion 33. The coupling efficiency between semiconductor element 30 and substrate 10 can be increased by the multi-step tapered structure.

Two dummy mesas 39 are located one each on two sides of mesa 35. It is possible to suppress the stress concentration on mesa 35 in the manufacturing step or the like. The mechanical strength is improved, and breakage can be suppressed.

Insulating film 11 covers silicon layer 16 and semiconductor element 30 of substrate 10. Since insulating film 11 functions as a cladding layer, it is possible to reduce the loss of light.

Semiconductor optical device 100 of FIG. 1 is a wavelength tunable laser diode. Semiconductor optical device 100 may be an optical device other than the wavelength tunable laser diode.

### Second Embodiment

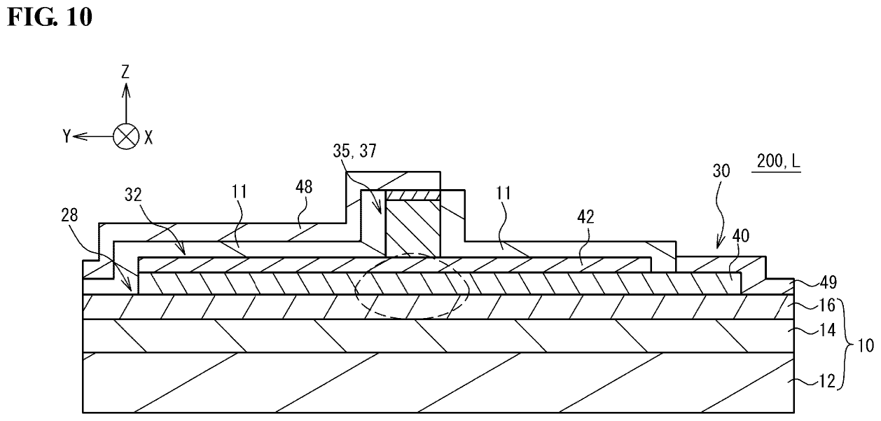

FIG. 10 is a cross-sectional view illustrating a semiconductor optical device 200 according to a second embodiment, in which the same position as FIG. 5 is illustrated. The description of the same configuration as that of the first embodiment will be omitted.

As illustrated in FIG. 10, semiconductor element 30 of semiconductor optical device 200 does not have a dummy mesa, but has mesa 35. Slab portion 32 extends from under mesa 35 to outside of mesa 35. Insulating film 11 covers side surfaces of mesa 35 and a top surface and a side surface of slab portion 32. Electrode 48 is provided on a top surface of mesa 35 and extends to the top surface of slab portion 32 and a top surface of slab portion 28.

According to the second embodiment, since semiconductor element 30 is bonded to slab portion 28, heat dissipation is high. Heat generated in semiconductor element 30 is released through slab portion 28. By suppressing temperature rise, deterioration of the characteristics is suppressed. Mesa 35 of semiconductor element 30 is located above slab portion 28. Light is distributed around mesa 35, and the mode shape is controlled by mesa 35. It is possible to reduce the loss of light

Although the embodiments of the present disclosure have been described in detail, the present disclosure is not limited to the specific embodiments, and various modifications and changes can be made within the scope of the gist of the present disclosure described in the claims.

What is claimed is:

1. A semiconductor optical device comprising:
a substrate having a silicon layer; and
a semiconductor element including a mesa, the semiconductor element being formed of a III-V group compound semiconductor and having an optical gain,
wherein the silicon layer includes a waveguide, a recess, and a first slab portion,
wherein the recess is a recessed portion lower than a surface of the waveguide and a surface of the first slab portion, and the recess is provided on each of two sides of the waveguide,
wherein the first slab portion is connected to the waveguide,
wherein the semiconductor element is bonded to the first slab portion, and
wherein the mesa is located on or above the first slab portion.

2. The semiconductor optical device according to claim 1,
wherein the first slab portion extends directly under the mesa and in a range extending from an end of the mesa by 3 μm or more.

3. The semiconductor optical device according to claim 1,
wherein the semiconductor element includes a second slab portion,
wherein the second slab portion is bonded to the first slab portion, and
wherein the mesa is located on or above the second slab portion.

4. The semiconductor optical device according to claim 3,
wherein the semiconductor element has a first semiconductor layer, an active layer, and a second semiconductor layer,
wherein the first semiconductor layer, the active layer, and the second semiconductor layer are stacked so as to be located closer to the substrate in this order,
wherein the first semiconductor layer has a first conductivity type,
wherein the second semiconductor layer has a second conductivity type,
wherein the mesa includes the second semiconductor layer, and
wherein the second slab portion includes the first semiconductor layer and the active layer.

5. The semiconductor optical device according to claim 4, comprising:
a first electrode separated from the mesa and electrically connected to the first semiconductor layer; and
a second electrode provided on or above the mesa and electrically connected to the second semiconductor layer,
wherein the first slab portion extends from under the mesa to under the second electrode.

6. The semiconductor optical device according to claim 3,
wherein the semiconductor element includes a projecting portion, and
wherein the projecting portion projects from the second slab portion to be located on or above the waveguide.

7. The semiconductor optical device according to claim 1,
wherein the semiconductor element includes two dummy mesas, and
wherein the two dummy mesas are located one each on two sides of the mesa.

8. The semiconductor optical device according to claim 1,
wherein the semiconductor element is in contact with the silicon layer.

9. A method of manufacturing a semiconductor optical device, the method comprising:
bonding a semiconductor element to a silicon layer of a substrate, the semiconductor element being formed of a III-V group compound semiconductor and having an optical gain; and
forming a mesa at the semiconductor element that has been bonded,
wherein the silicon layer includes a waveguide, a recess, and a slab portion,
wherein the recess is a recessed portion lower than a surface of the waveguide and a
surface of the slab portion, and the recess is provided on each of two sides of the waveguide,
wherein the slab portion is connected to the waveguide,
wherein, in the bonding, the semiconductor element is bonded to the slab portion, and
wherein the mesa is located on or above the slab portion.
